(19) United States
(12) Patent Application Publication
(10) Pub. No.: US 2002/0096495 A1
(43) Pub. Date: Jul. 25, 2002

(54) Apparatus and method for monitoring backflow vapors

(76) Inventors: Tue Nguyen, Fremont, CA (US); Manny Del Arroz, Diablo, CA (US)

Correspondence Address: Tue Nguyen, 496 Olive Ave., Fremont, CA, 94539, US

(21) Appl. No.: 09/766,137

(22) Filed: Jan. 19, 2001

(51) Int. Cl. G01L 21/30; C23C 16/00; C23F 1/00

(52) U.S. Cl. 216/59; 156/345.24; 156/345.26; 156/345.31; 118/712; 118/719

(57) ABSTRACT

An apparatus monitors process vapor includes a process chamber where the process vapor originates, the process chamber having a backflow pathway for removing the process vapor. The apparatus includes a sensor responsive to the process vapor in the backflow pathway and a controller coupled to the sensor. The controller activates a safety mode if the sensor detects that the concentration of the process vapor exceeds a selective threshold value.

### FIELD OF THE INVENTION

The present invention relates to the configuration and the method of an apparatus used in semiconductor wafer processing.

### BACKGROUND

Two of the most fundamental processes in integrated circuit (IC) fabrication are chemical vapor deposition (CVD) and etching. CVD processes use vapor precursors for the deposition of thin films on an IC substrate, while etching processes use vapor precursors for etching thin films on an IC substrate. The basic differences between CVD and etching processes are the precursors used and the process conditions applied, since the reaction systems used in both processes are similar. Basically, the reaction system used for both processes consists of a precursor delivery unit, a substrate and an energy source to decompose the precursor vapor to reactive species either to allow a thin film to form on the substrate (CVD process) or to etch an existing thin film on the substrate (etch process). Effective power sources are heat and plasma energy such as radio frequency (RF) power, microwave energy (MW) power, low frequency (10 KHz-1 MHz) power, and optical energy (e.g. a laser or ultraviolet light) for decomposing the introduced precursors. Also, the substrate could be biased or heated (100° C.-1200° C.), often in the case of CVD processes, to promote the reaction of the decomposed atoms or molecules and to control the physical properties of the deposited films.

The precursor delivery unit is responsible for the introduction of precursor vapor into the reactor. Precursors are chemical compounds that could be brought together in a reactor chamber. The reactive precursors either decompose or react with each other under a catalyst or an energy source. Non-reactive precursors such as helium, nitrogen, and argon are sometimes used to dilute the reactive precursors.

Traditionally, precursors used in semiconductor CVD processes are gaseous. An example of a CVD process to deposit silicon dioxide (SiO₂) is to use gaseous precursors such as silane gas (SiH₄) and oxygen gas (O₂):

SiH₄(gas)+O₂(gas)−(heat)→SiO₂(solid)+2H₂(gas)

The basic requirements of a precursor are that the desired product (in this example, SiO₂) is solid, and all other products are gases (in this example, H₂) to be exhausted away. The energy required for the reaction to take place is the thermal energy, about 400-800° C.

To broaden the processes, more and more liquid and solid precursors have been used, especially in the area of metal-organic chemical vapor deposition (MOCVD). To perform this MOCVD task, a liquid precursor is typically turned into vapor, and the vapor is then decomposed and reacts on the substrate. A solid precursor must often be dissolved into a solvent to form a liquid precursor. The liquid precursor then needs to be converted into vapor phase before being introduced into the deposition zone. An example of a CVD process to deposit copper (Cu) is to use liquid precursor Copper HexaFluoroACetylacetone TriMethylVinylSilane (hfac-copper-tmvs, C₅HO₂F₆—Cu —C₅H₁₂Si):

Cu-hfac-tmvs(liquid)−(heat)→Cu-hfac-tmvs(vapor)

2Cu-hfac-tmvs(vapor)−(heat)→Cu(solid)+hfac-Cu-hfac(vapor)+2tmvs(vapor)

Both CVD and etching processes often occur at reduced atmospheric pressure (typically Torr pressure for CVD processes and milliTorr pressure for etching processes) to prevent contamination and impurity incorporation. Typical process reactor then includes a process pump to maintain this reduced atmospheric pressure. These processes also involve hazardous chemicals. Their by-products are also hazardous. The process vapors, composed of the precursors and their by-products, are often toxic chemicals, not only to people, environment, but also to selected metals as well. Therefore all the materials in contact with the precursors and their by-products are often chosen to withstand the possible damage caused by them. For example, etching processes often involve fluorine or chlorine, thus very corrosive. The pump material selected for these applications needs to be treated, such as Teflon coated, to prevent damage. Exhaust flows are also treated to remove all toxic materials before being released to the external atmosphere. Sometimes a trap is used to capture all or part of the toxic materials for re-use or for disposal. Sometimes an abatement unit is used to reduce the toxic components in the exhaust flows before sending them to a treatment unit such as a scrubber.

Since most semiconductor processes occur at reduced atmospheric pressure, often a transfer chamber is needed to prevent exposing the process chamber to atmosphere. FIG. 1 shows a prior art semiconductor processing system having a single transfer housing. The process chamber 1 is always kept under reduced atmospheric pressure with the pumping unit 5. The process evacuation pathway 4 is responsible for evacuating all process vapor in the process volume 2 to atmosphere 7. The process evacuation pathway 4 includes the pumping unit 5 and the process vapor treatment unit 6. The process vapor treatment unit 6 is responsible for treating the process vapor, rendering the process vapor harmless before releasing it into atmosphere 7. The pumping unit 5 and the treatment unit 6 are specially constructed to withstand the damage such as corrosion and etching caused by the process vapor. To start processing, the transfer chamber 13 is vented to atmosphere by a non-reactive, safe gas such as nitrogen or argon (not shown). When the pressure in the transfer chamber 13 reaches atmospheric pressure, the door 12 to the transfer chamber 13 opens and a wafer is introduced into the transfer chamber 13. Door 12 then closes, and the transfer chamber 13 is pumped down to reduced atmospheric pressure through the evacuation pathway 14. The transfer evacuation pathway 14 is responsible for evacuating the transfer volume 11 to atmosphere 16 through the pumping unit 15. Since the transfer volume contains only non-reactive and safe gas, the pumping unit 15 is normally not constructed to withstand the harsh environment as the pumping unit 5 of the process evacuation pathway 4. Also for the same reason, the transfer evacuation pathway 14 normally does not have a toxic treatment unit. Once the transfer chamber 13 achieves similar reduced atmospheric pressure as the process chamber 1, the process door 10 between the transfer chamber 13 and the process chamber 1 opens. Wafer 3 is then transferred into the process chamber 1. Door 10 then closes. The process vapor 8 is then introduced into the process chamber 1 through the process gas inlet 9 for processing the wafer. During the process vapor flow, in order to maintain a desired pressure in the process chamber, the process evacuation pathway 4 is working continuously to evacuate residues, precursor by-products, and non-reactive process precursors generated by the reaction of the process vapor 8 with wafer 3. The process evacuation pathway 4 often includes a pump unit 5 to maintain the reduced atmospheric pressure, an abatement unit (not shown) to reduce the toxic or harmful components of the exhaust flow, a treatment unit 6 to completely neutralize the exhaust flow to render it harmless to the environment before releasing it to the atmosphere. Sometimes the exhaust flow could cause damage to the components of the process evacuation pathway (for example the hfac-Cu-hfac by-product in liquid copper precursor reaction is very corrosive to stainless steel), therefore these components are carefully selected or treated to withstand the damage caused by the exhaust flow, such as Teflon coated to prevent etching from fluorine or chlorine-based precursors. Once the process is completed, the process vapor 8 stops flowing while the process volume 2 continues being pumped out through the process evacuation pathway 4. Then the door 10 to the process chamber 1 opens, and wafer 3 is transferred from the process chamber 1 to the transfer chamber 13. Door 10 closes, and the transfer chamber 13 is vented to atmosphere with non-reactive gas such as nitrogen or argon. Once the transfer chamber 13 reaches atmosphere, door 12 opens and the wafer 3 is taken out of the transfer chamber 13. The processing system is now ready to process the next wafer.

To improve the throughput, a cassette chamber is coupled to the transfer chamber for storing many workpieces. The opening to atmosphere is now at the cassette chamber, and the transfer chamber and the process chamber will not be exposed to atmosphere anymore. FIG. 2 shows a prior art semiconductor processing system having two transfer housings. The first transfer chamber 23 is often called a cassette module (or a cassette chamber), and is used to store the wafers before transferring them to the second transfer chamber 13 and to the process chamber 1. The second transfer chamber 13 is often called a transfer module (or sometimes simply transfer chamber). This system increases the throughput of the processing because the first transfer chamber 23 will need to be vented only once for a cassette of wafers. A typical operation is as followed. Door 22 to the first transfer chamber (or cassette module) 23 opens, and a cassette of wafers is put into the first transfer chamber 23. First transfer chamber 23 is pumped down to reduced atmospheric pressure through the transfer evacuation pathway 24 with pumping unit 25 to atmosphere 26. Door 12 to the second transfer chamber (or transfer module) 13 then opens and one wafer is taken into the second transfer chamber 13. Door 12 closes, door 10 to the process chamber 1 opens and the wafer is taken into the process chamber 1, then door 10 closes and the process starts. After the process ends, the process chamber 1 is pumped down to base pressure (the lowest pressure obtainable by the available pump equipment 5) to evacuate as much as possible the process vapor in the process chamber 1. Then door 10 opens, the wafer returns to the second transfer chamber 13 and door 10 closes. Door 12 opens, the wafer returns to the first transfer chamber 23, and a new wafer is then being transferred into the second transfer chamber 13. The cycle continues until all the wafers in the first transfer chamber are processed. The transfer module could have many process chambers attached to it to allow the wafer to be processed in different process chambers for different processing steps.

The cassette chamber and the transfer chamber are only exposed to air or inert gas since there is no process vapor in these chambers, therefore the components of the cassette evacuation pathway and the transfer evacuation pathway are not rated for toxic or corrosive environment. Furthermore, the transfer module sometimes employs more than one transfer chamber to increase the number of process chambers connecting to it, or to improve the vacuum at an inner stage of the transfer chamber.

The use of liquid precursors in a process can cause problems. Normally with gaseous precursors, it takes only seconds to evacuate the process vapor that consists of process precursors and their by-products because the backflow is small. With liquid precursors, the evacuation process would take many minutes or even hours because the liquid vapor could be adsorbed at the surface of the chamber wall and could only be desorbed very slowly. Therefore with liquid precursors, significant amount of the process precursors and their byproducts still exist in the process chamber, hence increasing the amount of process vapor in the backflow. Solutions to reduce the amount of these process vapors in the process chamber such as heating the chamber wall to increase the desorption of precursor vapor, could cause side effects to the processes such as deposition on the chamber wall and chamber conditioning problems.

### SUMMARY

An apparatus and method are disclosed for monitoring the presence of process vapor (including process precursors and their by-products) in the transfer chamber and cassette chamber due to a backflow pathway from the process chamber when a partition door between the process chamber and the transfer chamber opens.

In one aspect, the apparatus includes a process housing defining a process volume and a process evacuation pathway from the process volume to atmosphere. The process housing is for processing a workpiece and the process evacuation pathway is responsible for the evacuation of process vapor in the process volume. The apparatus further includes a plurality of transfer housings coupled linearly to each other and to the process housing. Each transfer housing defines a transfer volume and the first transfer housing has at least a transfer opening to atmosphere. The first transfer housing is coupled to the second transfer housing, and so on, and the last transfer housing is coupled to the process housing so that the transfer housings are for transferring the workpiece to and from the process housing. The last transfer housing and the process housing in combination define a backflow pathway from the process volume to the transfer volume. The apparatus further includes at least one sensor operative in at least one configuration to be substantially responsive to the process vapor in the backflow pathway.

Implementations of the above aspect may include one or more of the followings. The last transfer housing can include a transfer module for the movement of workpieces to and from the process volume, and at least one sensor can be coupled to the transfer module for monitoring the level of process vapor from the backflow pathway in the transfer module to prevent possible cross contamination between process chambers connecting to this transfer module. The first transfer housing can include a cassette module for the storage of workpieces to be transferred to or received from the process volume, and at least one sensor can be coupled to the cassette module for monitoring the level of process vapor from the backflow pathway in the cassette module to prevent possible releasing of the process vapor into atmosphere. The sensor can be located in the backflow pathway to monitor the level of process vapor when it backflows from the process chamber to the transfer chamber. The sensor can also be located in the transfer volume to monitor the level of process vapor in the transfer volume. The sensor can include a gas chromatography device, or a residual gas analyzer to detect the presence of certain chemical compounds in the process vapor. The principle of a sensor is normally based on the separation of chemical compounds using different techniques such as energy separation, mass separation, charge separation, and adsorption separation. The most common sensors are chromatography devices (using adsorption separation technology) and residual gas analyzers (using mass and charge separation technology), but other types of sensors or analyzers can be used to measure the process vapors. The process vapor in the backflow pathway can include at least one liquid vapor component, a precursor, precursor byproducts or other toxic substances involved in a chemical vapor deposition technique.

The apparatus can further include a backflow removal element which is made responsive to the sensor and thus can be responsible for removing the process vapor in the backflow pathway when the sensor indicates a level of process vapor exceeding a threshold limit. The backflow removal element is disclosed in a co-pending application, entitled “Apparatus and method for the removal of backflow vapors” of the same author. The backflow removal element can include at least one of the followings: a gas purging unit, a venting unit, and a trapping unit. The gas purging unit can employ higher pressure in the transfer volume, thus creates a positive flow against the backflow pathway when the process partition door is opened. The gas purging unit can employ high flow of purging gas flowing from the transfer volume toward the process volume, thus creates a positive flow against the backflow pathway when the process partition door is opened. The gas purging unit can purge the process vapor in the backflow pathway toward the transfer evacuation pathway during the workpiece transfer movements when the process partition door is opened and also after the door is already closed. The gas purging unit can also employ high flow of purging gas directing from the transfer volume toward the transfer evacuation pathway, thus creates a positive flow directing the backflow pathway toward the transfer evacuation pathway. An added benefit is that since the purging can be done anytime, significant reduction of process vapor in the transfer volume due to backflow is possible. The backflow removal element can also include a venting unit, such as a pump, a fan, etc. to vent the process vapor in the backflow pathway to the exhaust unit. This venting unit should be specially constructed to withstand possible damage caused by the process vapor. After the process partition door is closed, this venting element can completely vent all the process vapor from the backflow pathway out of the transfer volume toward the exhaust. Since process vapor is present, all components of this exhaust pathway need to be specially constructed so as not to be damaged by the corrosiveness of the process vapor. Also, a combination of purging gas and venting through the exhaust pathway can be used to speed up the removal of process vapor from the backflow pathway. Lastly, the backflow removal element can include a process vapor trap, such as a cold trap, a heat trap, a plasma trap, an ionic trap, an absorption or adsorption trap, for trapping the process vapor from the backflow pathway. The trap can be coupled to the exhaust pathway to trap the process vapor on its way out toward the atmosphere. The trap can be a cold trap in the range of about 25° C. to −200° C. to cause condensation of the process vapor. This cold trap can be coupled to the transfer housing to trap the process vapor in the transfer volume before going toward the exhaust pathway.

The apparatus can include at least one indicator responsive to the sensor to provide feedback of the status of the process vapor level. The indicator can be responsive to a selective threshold value of the concentration of the process vapor. The indicator can be mounted in such a way so as to be readily accessible to an operator. The operator could decide whether or not to start a safety step such as activating a backflow removal element or waiting for the process vapor to decrease before continuing the next step. The types of sensor feedback can vary depending upon the sensor type, the location of the sensor and whether or not a particular operator is needed. For example, the feedback from these sensors could include a warning light or other signals indicating whether it is safe to open a particular door, a gauge or other measure indicating the concentration of the vapors, an automatic locking unit or other interlocks such that the door can automatically lock when the concentration of fumes exceeds a particular threshold, or an automatic activating of a backflow removal element when the sensor indicates the presence of an excess amount of process vapor.

The indicator can be linked to a computer, so that the computer could decide whether or not to start a safety step. The indicator includes at least one of the followings: an alarm, an analog readout, a digital readout, a concentration gauge, a warning light, an analog output signal, or a digital output signal. The alarm, the digital readout, and the warning light could warn the operator that the level of process vapor exceeds a certain threshold value. The analog readout and the concentration gauge could indicate to the operator the level of process vapor. The analog output signal could provide the computer with the level of the process vapor. The digital output signal could inform the computer whether or not the process vapor exceeds a certain threshold value.

In a second aspect, a method is disclosed to monitor the backflow process vapor from a process chamber to a transfer chamber and then take necessary actions. The method includes the steps of a) monitoring a sensor responsive to the process vapor in the backflow pathway; and b) activating a safety step if the sensor detects a concentration of the process vapor that exceeds a selective threshold value. The safety step can simply be waiting for the amount of process vapor to decrease, or activating a backflow removal element to reduce the amount of process vapor, or overriding the sensor signal and bypassing to the next step.

The implementation of a backflow removal element can include purging the backflow pathway, using a purging and pumping cycle to substantially remove process vapor in the backflow pathway, or trapping the process vapor in the backflow pathway. The purging step can push the process vapor back toward either the process volume, or the transfer evacuation pathway. The trap can be coupled to the transfer evacuation pathway, or coupled to the transfer housing itself. To monitor and reduce the precursor vapor in the backflow pathway, these monitors and removal steps can be inserted anywhere in the sequence of the workpiece movements from the cassette module to the transfer module and then to the process chamber. The monitors and removal steps can start at the beginning of the process sequence and only stop when all the workpieces are completely processed, or they can start only before and after the process door opens when there is significant backflow.

In yet another aspect, an apparatus to monitor process vapor includes a process chamber where the process vapor originates, the process chamber having a backflow pathway for removing the process vapor. The apparatus includes a transfer chamber coupled to the process chamber, a sensor responsive to the process vapor in the backflow pathway; and a controller coupled to the sensor, the controller activating a safety mode if the sensor detects that the concentration of the process vapor exceeds a selective threshold value.

Advantages of the invention may include one or more of the following. The apparatus addresses a need for advanced processing techniques and increasing environmental concerns because measurable amount of the process vapor could still exist in the process chamber, especially when using liquid precursors, and the presence of this process vapor in the transfer chamber or cassette chamber could cause significant damage, either to the operator, the environment, or to the equipment. The apparatus avoids releasing harmful vapors to the environment through the cassette chamber door when workpieces are taken into and out of the cassette chamber, or through the cassette or transfer evacuation pathway. By avoiding or minimizing the release of these harmful vapors, the apparatus minimizes potential of damage to the components in these evacuation pathways since these components, such as vacuum pumps, are not rated for toxic or corrosive substances.

### Incorporated Disclosures

The invention described herein can be used in conjunction with invention described in the following applications, the contents of which are incorporated by reference:

Ser. No. 09/589,636, in the name of Tue Nguyen, titled “High Pressure Chemical Vapor Trapping System”, filing date Jun. 7, 2000, assigned to the same assignee, attorney docket number SIM013.

Ser. No. 09/589,633, in the name of Tue Nguyen and Craig Alan Bercaw, titled “Visual Indicator Cold Trapping System”, filing date Jun. 7, 2000, assigned to the same assignee, attorney docket number SIM014.

Ser. No. ______, in the name of Tue Nguyen, titled “Apparatus and method for the removal of backflow vapors”, filing date ______, assigned to the same assignee, attorney docket number SIM031.

### BRIEF DESCRIPTION OF THE DRAWINGS

FIG. 1 shows a prior art semiconductor processing system having a single transfer housing.

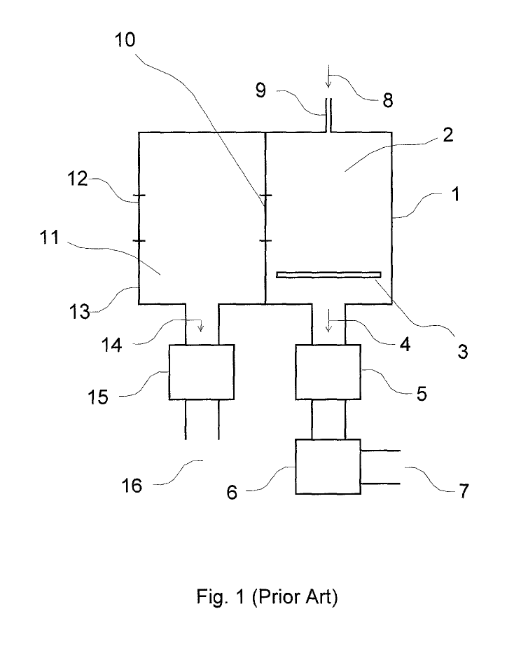

FIG. 2 shows another prior art semiconductor processing system having two transfer housings.

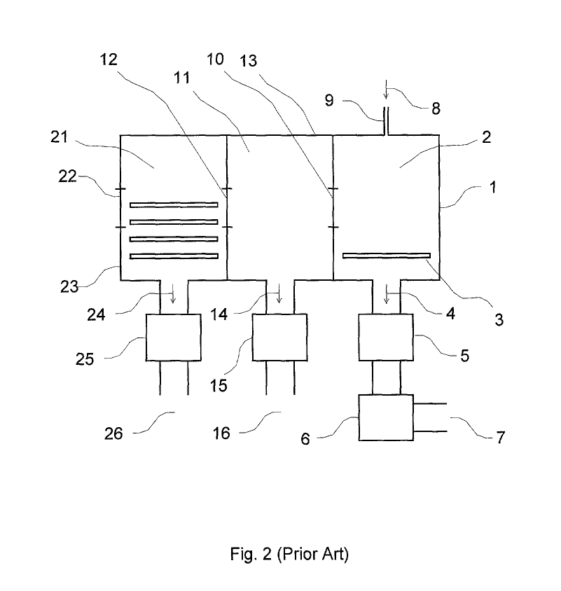

FIG. 3 shows an apparatus on a single transfer housing system.

FIG. 4 shows an apparatus on a two transfer housings system.

FIG. 5 shows a workpiece transfer movements and possible backflow monitoring steps in a single transfer housing system.

FIG. 6 shows the workpiece transfer movements and possible backflow monitoring steps in a two transfer housings system.

### DESCRIPTION

An apparatus and method for monitoring backflow vapors in workpiece processing is disclosed. The apparatus includes a sensor which is responsive to the backflow of process vapor in a workpiece processing apparatus. The sensor includes either a gas chromatography device or a residual gas analyzer (RGA) to measure the level of one or more types of vapors of process chemicals in the backflow pathway. In some embodiments, the sensor may be coupled to a cassette module used to store the workpieces, or coupled to the transfer module used to transfer the workpieces between the cassette module and the process chamber. In another aspect of the invention, the sensor is used to provide feedback to an operator of the apparatus or to the computer controlling the apparatus. The type of feedback can vary, depending upon the type of the sensor, the location of the sensor, the needs of a particular operator, and the algorithm of the controlling software. For example, the feedback from these sensors could include one or more of the followings: a warning light or other signals indicating whether it is safe to open a particular door, a gauge or other measure indicating the concentration of the vapors or an automatic locking unit or other interlock such that the door can automatically lock when the concentration of fumes exceeds a particular threshold. In another embodiment, the sensor is coupled to a backflow removal element such as a purging gas unit, a venting element, or a trapping unit. The backflow removal element could reduce the level of process vapor measured by the sensor until it reaches an acceptable level. In still other embodiments, different types of sensors or analyzers other than RGA can be used to measure other types of vapors.

The apparatus according to the present invention includes a sensor incorporated in the backflow pathway to monitor the presence of precursors and their by-products. The apparatus enables the monitoring of the cassette module for toxic substances to alert the operator from the possible danger caused by the backflow of precursor vapor and to allow for remedial actions. The apparatus also enables the monitoring of the cassette module for toxic substances so as to alert the controlling computer of the presence of high level of precursor vapor in the backflow pathway that could be released into atmosphere. Finally, the apparatus allows the monitoring of the transfer module for toxic substances so as to alert the controlling computer of the presence of high level of precursor vapor in the backflow pathway which could cause cross contamination.

The backflow pathway carries the process vapors composed of precursor vapors and their by-products from a process housing to a directly coupled transfer housing. To evacuate all process vapors in the process volume, the process housing already has a process evacuation pathway which is normally well designed to handle the toxicity and corrosiveness of the precursors and their by-products; however, measurable amount of process vapor could still backflow toward the transfer chamber. To move a workpiece into and out of the process housing, a transfer housing is coupled to the process housing. Normally a process partition door is present between the process housing and the transfer housing. This partition door is opened during the transfer of the workpiece and closed during the processing of the workpiece to prevent precursors and their byproducts from escaping the process volume. However, some precursors and their by-products might still be present after processing, especially with liquid precursor vapors, and thus can escape to the transfer housing during the transfer of the workpiece. This forms the backflow of the precursor and their byproducts.

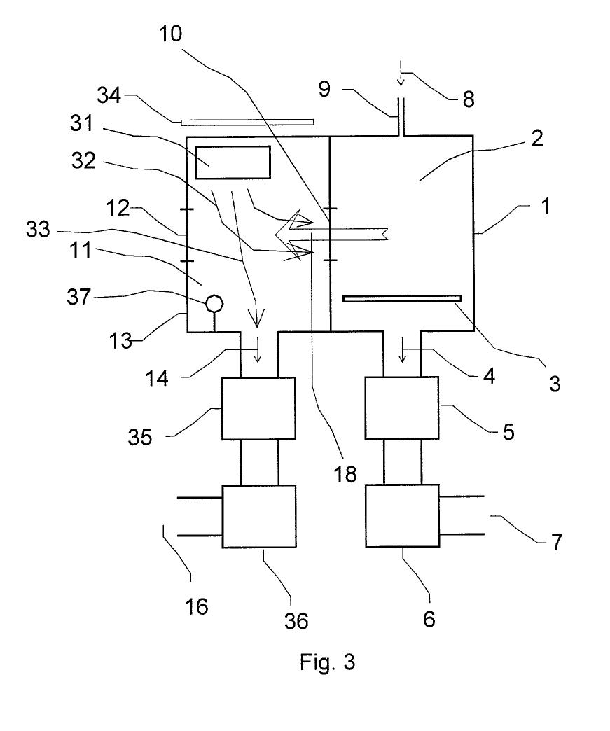

FIG. 3 shows the present invention apparatus on a single transfer housing system. It includes a sensor 37 to alert the operator or the controlling computer regarding to the level of process vapor in the transfer volume 11 so appropriate action can be taken. The backflow pathway 18 can carry significant process vapor from the process volume 2 to the transfer volume 11 when the partition door 10 is opened. For gaseous precursors, the backflow is small after a few seconds of pumping the process volume 2 through the evacuation pathway 4 before the partition door 10 is opened. However, with liquid precursor vapor, the backflow 18 is significant. Also, the presence of liquid process vapor in the process volume 2 is sometimes needed for conditioning the process chamber 1, thus further increase the backflow 18. The presence of process vapor in backflow 18 causes significant risk both to the equipment and to the operators. The pumping unit 15, if not specially protected, could fail prematurely because of the process vapor. The process vapor, if not removed, could be released into the face of the operator when the transfer chamber door 12 is opened. The process vapor, if not removed, could cause damage to the environment 16 without a treatment unit at the transfer evacuation pathway 14. Thus the apparatus includes several of the backflow remover elements responsive to the sensor 37 to remove the backflow process vapor. These backflow remover elements can be used together to improve the removing capability. A backflow remover element 31 is a gas purging unit. A gas purging unit could include a non-reactive or inert gas inlet to purge the precursor vapor backflow. The gas purging unit 31 could raise the pressure in the transfer volume 11, or could produce a high flow 32 to push the backflow back toward the process chamber 1 when the process partition door 10 is open. This method is not very effective because no matter how high the pressure or the flow, there is always some backstream flow of precursor vapor. Therefore further purging is needed after the partition door 10 is closed. The gas purging unit 31 produces a gas flow 33 to push the backflow toward the transfer evacuation pathway 14. Working together with the pumping unit 35, this provides an effective way to prevent the backflow from reaching the door 12. The pumping unit 35 needs to be specially constructed to prevent damage due to the process vapor flow. Also since the transfer evacuation pathway 14 now carries the process vapor from the backflow pathway, another backflow remover element is needed to remove the process gas from the transfer evacuation pathway 14. A backflow remover element 36 is a process vapor trap to trap all process vapors. The preferred embodiment is a cold trap, in the range of 25° C. to −200° C., to condense and capture all process vapors to prevent them from being released to atmosphere 16. Sometimes a heat trap is used in conjunction with a cold trap. The heat trap furthers the reactions, so that the process vapor will become less precursor vapor and more precursor by-products. The temperature of the heat trap is typically between 100° C. and 500° C. Another backflow remover element is the cold trap 34 which is used to cool down the transfer chamber 13 to the trap temperature, thus turning it into a huge cold trap. The drawback of using this cold trap 34 is that the process vapor will still be captured in the transfer volume 11, thus when door 12 is opened, the operator might still be exposed to some process vapor coming out from the trap.

There could be a plurality of transfer housings. These transfer housings are coupled linearly to each other and to the process housing. The first housing is coupled to the second housing, and so on, and the last housing is coupled to the process housing. The first transfer housing has an opening to atmosphere for the workpiece to be transferred into and out of the transfer housing. The transfer housings are coupled to each other so that the workpiece can transfer from the first transfer housing to the last transfer housing. These transfer housings further have partition doors in between to isolate the individual housing. Similar to the process partition door, these partition doors are opened only during the transfer of the workpiece through the transfer housings that are connected, and are closed at all other times. The last transfer housing is coupled to the process housing through the process partition door. The precursors and their by-products escape the process housing through the backflow pathway, and could travel through all the transfer housings. The precursors and their byproducts could leak out to atmosphere at the first transfer housing when the partition door is opened to transfer the workpiece, or could leak out through the pump in any of the transfer housings. The first transfer housing could be a cassette module for the storage of the workpieces to be transferred to and from the process housing. The last transfer housing could be a transfer module for the transfer of the workpieces directly to and from the process housing.

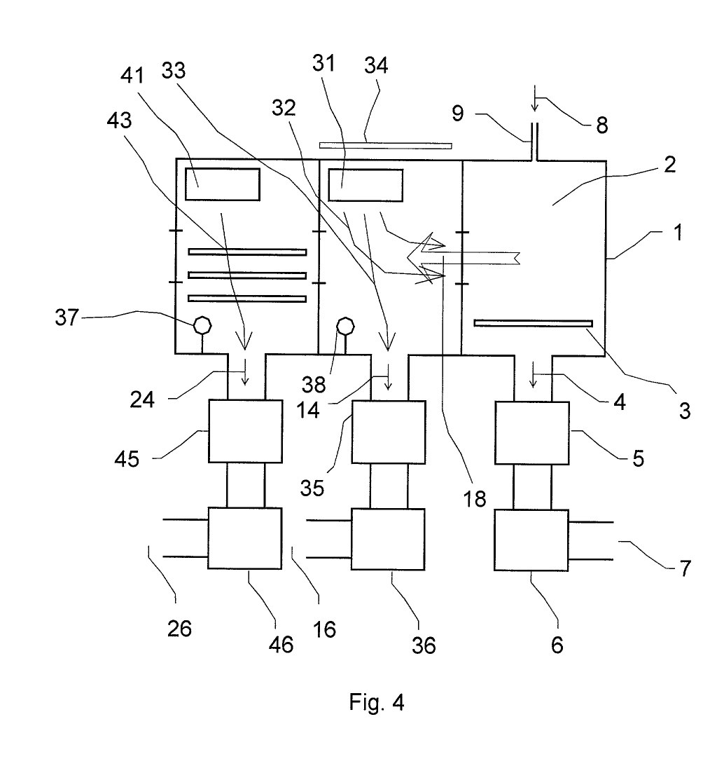

FIG. 4 shows the apparatus on a two transfer housings system. In this configuration, the drawback of the cold trap 34 disappears because the process vapor is trapped in the second transfer chamber and with the door between the first and second transfer chamber closed, no process vapor can escape. The apparatus includes the sensor 37 in the first transfer chamber and sensor 38 in the second. Similar backflow remover elements as in FIG. 3 can be put on the first and second transfer chambers, such as gas purging units 41 and 31, process vapor traps 46 and 36, and specially constructed pumping units 45 and 35. We have observed damage to a regularly constructed pumping unit 45 connected to the first transfer chamber when running liquid copper precursor (copper-hfac-tmvs). The copper precursor and its by-products escape the process chamber through the backflow pathway, they further escape the second transfer chamber 13 because the doors 12 and 10 are often opened at the same time to improve throughput, and are being pumped out through the first transfer evacuation pathway 24, thus damaging the pumping unit 45.

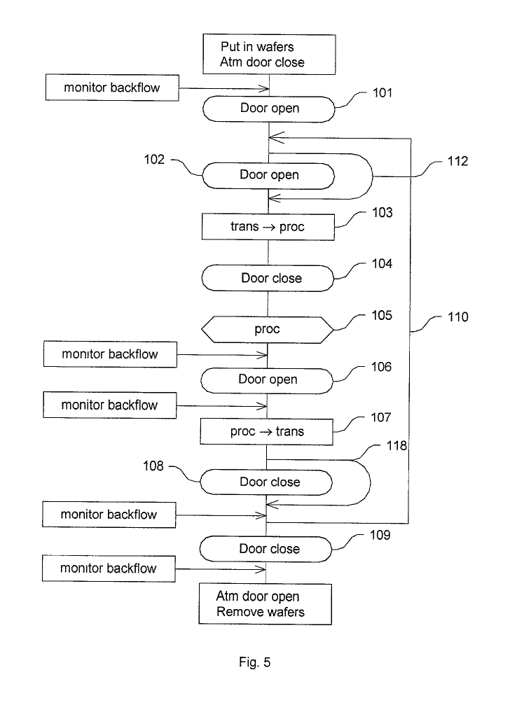

FIG. 5 shows the workpiece transfer movements and possible backflow monitoring steps in a single transfer housing system. The operator opens the door to the atmosphere (atm door) and put the workpieces in the transfer chamber. The atm door closes and the transfer chamber pumps down to reduced atmospheric pressure. To start the process sequence, the door between the process and the transfer chamber opens (step 101). Step 102 (opens this door) or step 112 (skips opening the door) is for looping purpose. Then the workpiece is transferred from the transfer chamber to the process chamber (step 103). Then the door between the process and the transfer chamber closes (step 104). Process starts (step 105). Then the door between the process and the transfer chamber opens (step 106). Then the workpiece is transferred from the process chamber to the transfer chamber (step 107). Then the door between the process and the transfer chamber closes (step 108). The sequence continues back to step 102 again for the next workpiece (step 110). Steps 108 and 102 could be skipped (steps 118 and 112) and the door just remains open during the time when an old workpiece is transferred out of and a new workpiece into the process chamber. After the last workpiece, the door closes (step 109). The operator then could vent the transfer chamber to atmospheric pressure, open the atm door to the atmosphere, and remove the workpieces. The backflow monitoring step could be inserted anywhere in this sequence. For a most complete backflow monitoring step, the backflow monitoring starts when the process sequence begins (before step 101), and stops when the process sequence ends. A shorter backflow monitoring step starts before the process partition door opens (before step 106) to monitor the backflow and stops after the door closes (after step 104). Another shorter backflow monitoring step starts after the process partition door opens (after step 106) and stops before the door closes (before step 104). The shortest backflow monitoring step runs only during step 110. The backflow monitoring step includes a safety step, such as a backflow removal step if the level of process vapor exceeds a certain threshold value.

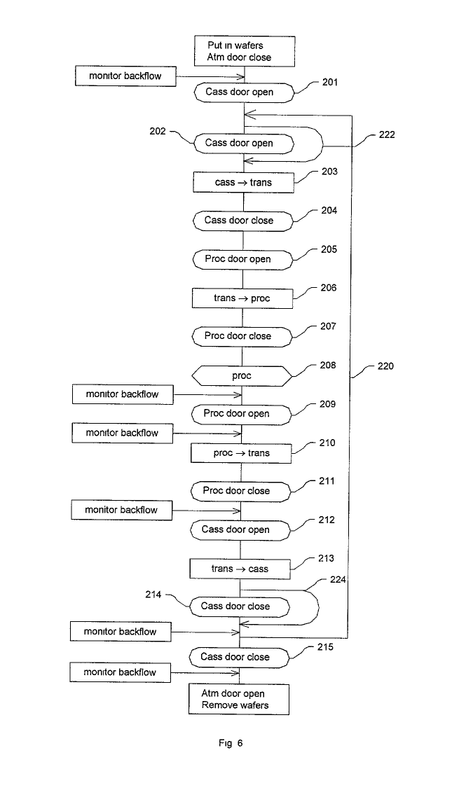

FIG. 6 shows the workpiece transfer movements and possible backflow monitoring steps in a two transfer housings system having one transfer module and one cassette module. The operator opens the door to the atmosphere (atm door) and put the workpieces in the cassette chamber. The atm door closes and the cassette chamber pumps down to reduced atmospheric pressure. When the process sequence starts, the cassette door opens (step 201), and a workpiece is transferred from the cassette to the transfer module (step 203). The cassette door closes (step 204). The process door opens (step 205), and the workpiece is transferred from the transfer module to the process chamber (step 206). The process door closes (step 207) and process starts (step 208). After the workpiece is finished processing, the process door opens (step 209), and the workpiece is transferred from the process chamber back to the transfer module (step 210). The process door closes (step 211), and the cassette door opens (step 212). The workpiece is now transferred from the transfer module to the cassette module (step 213). The cassette door closes (step 214), and the sequence continues for the next workpiece (step 220). Often for a faster movement, the cassette door remains open during the time when a processed workpiece comes in and a new workpiece goes out (steps 202 and 214 become steps 222 and 224). After all the workpieces are processed, the cassette door closes (step 215) and the cassette of workpieces is ready to be taken out. The operator then could vent the cassette chamber to atmospheric pressure, open the atm door to the atmosphere, and remove the workpieces. Similar to the sequence with one transfer chamber, the backflow monitoring step can be inserted anywhere in the sequence. For a complete backflow monitoring, the backflow monitoring step starts when the process sequence begins (before step 201) and stops when the process sequence ends (after step 215). The backflow monitoring step could start after the process partition door closes (after step 212), and stop before the process partition door opens (before step 205), to prevent the backflow monitoring from affecting the process chamber.

Although a preferred embodiment of practicing the method of the invention has been disclosed, it will be appreciated that further modifications and variations thereto may be made while keeping within the scope of the invention as defined in the appended claims.

What is claimed is:

1. An apparatus to monitor backflow vapors in workpiece processing, comprising:
a process housing defining a process volume and having a process evacuation pathway from the process volume to atmosphere;
one or more transfer housings to transfer a workpiece to and from the process housing, each transfer housing defining a transfer volume, the one or more transfer housings and the process housing in combination defining a backflow pathway from the process volume to the transfer volume; and
a sensor to monitor process vapor in the backflow pathway.

2. Apparatus as in claim 1, wherein one of the transfer housings includes a transfer module for the movement of workpieces to and from the process volume, and the sensor is coupled to the transfer module for monitoring the level of process vapor from the backflow pathway in the transfer module.

3. Apparatus as in claim 1, wherein one of the transfer housing includes a cassette module for the storage of workpieces to be transferred to and from the process volume, and the sensor is coupled to the cassette module for monitoring the level of process vapor from the backflow pathway in the cassette module.

4. Apparatus as in claim 1, wherein the sensor is located in the backflow pathway.

5. Apparatus as in claim 1, wherein the sensor is located in the transfer volume.

6. Apparatus as in claim 1, wherein the sensor includes a gas chromatography device.

7. Apparatus as in claim 1, wherein the sensor includes a residual gas analyzer.

8. Apparatus as in claim 1, wherein the process vapor in the backflow pathway includes at least one liquid vapor component.

9. Apparatus as in claim 1, wherein the process vapor in the backflow pathway includes at least one precursor, precursor byproduct or other toxic substance generated in a chemical vapor deposition.

10. Apparatus as in claim 1, further including a backflow removal element, wherein the backflow removal element is responsive to the sensor, and wherein the backflow removal element removes the process vapor in the backflow pathway.

11. Apparatus as in claim 10, wherein the backflow removal element includes at least one of: a purging gas unit, a venting element, and a trapping unit, and wherein the backflow removal element is responsible for removing the process vapor in the backflow pathway.

12. Apparatus as in claim 1, including at least one indicator responsive to the sensor.

13. Apparatus as in claim 12, wherein the indicator is responsive to a selective threshold value of the concentration of the process vapor.

14. Apparatus as in claim 12, wherein the indicator is mounted so as to be readily accessible to an operator to start a safety step before continuing to the next step.

15. Apparatus as in claim 12, wherein the indicator is coupled to a computer, wherein the computer determines whether or not to start a safety step before continuing to the next step.

16. Apparatus as in claim 12, wherein the indicator includes at least one of: an alarm, an analog readout, a digital readout, a concentration gauge, a warning light, an analog output signal, and a digital output signal.

17. A method to monitor process vapor in a backflow pathway from a process chamber to a transfer chamber, the process vapor originating from the process chamber with the process chamber having a separate evacuation pathway for removing the process vapor, the method comprising
a) monitoring a sensor responsive to the process vapor in the backflow pathway; and
b) activating a safety step if the sensor detects that the concentration of the process vapor exceeds a selective threshold value.

18. A method as in claim 17 wherein the activating a backflow removal element step includes purging the backflow pathway.

19. A method as in claim 17 wherein the activating a backflow removal element step includes a purging and pumping cycle to substantially remove process vapor in the backflow pathway.

20. A method as in claim 17 wherein the activating a backflow removal element step includes trapping the precursor vapor in the backflow pathway.

21. A method as in claim 17 wherein the process vapor in the backflow pathway includes at least one liquid vapor component.

22. A method as in claim 17 properly inserted into the workpiece transfer movements for monitoring the process vapor in the backflow pathway.

23. An apparatus to monitor process vapor, comprising:
a process chamber where the process vapor originates, the process chamber having a backflow pathway for removing the process vapor;
a sensor responsive to the process vapor in the backflow pathway; and
a controller coupled to the sensor, the controller activating a safety mode if the sensor detects that the concentration of the process vapor exceeds a selective threshold value.

24. An apparatus as in claim 23, wherein the controller waits for the process vapor to decrease, activates a backflow removal element to reduce the amount of process vapor, and overrides the sensor signal.

25. An apparatus as in claim 23, wherein the sensor includes either a gas chromatography device or a residual gas analyzer (RGA) to measure the level of one or more types of vapors of process chemicals in the backflow pathway.

26. An apparatus as in claim 23, wherein the sensor is coupled to a cassette module used to store a workpiece.

27. An apparatus as in claim 23, wherein the sensor is coupled to a transfer module used to transfer the workpiece between a cassette module and the process chamber.

28. An apparatus as in claim 23, wherein the sensor is used to provide feedback to an operator or to the controller.

29. An apparatus as in claim 28, wherein the feedback from the sensors includes one or more of the followings: a warning light or other signals indicating whether it is safe to open a particular door, a gauge or other measure indicating the concentration of the vapors or an automatic locking unit or other interlock such that the door can automatically lock when the concentration of fumes exceeds a particular threshold.

30. An apparatus as in claim 23, wherein the sensor is coupled to a backflow removal element.

31. An apparatus as in claim 30, wherein the backflow removal element is one of a purging gas unit, a venting element, or a trapping unit.

32. An apparatus as in claim 30, wherein the backflow removal element reduces the level of process vapor measured by the sensor until it reaches an acceptable level.

33. An apparatus as in claim 23, further comprising a transfer chamber coupled to the process chamber.
